(19) United States
(12) Patent Application Publication
(10) Pub. No.: US 2026/0171828 A1
(43) Pub. Date: Jun. 18, 2026

(54) CHARGING EVALUATION METHOD BASED ON STATES OF HEALTH OF ONE OR MORE BATTERIES AND USE THEREOF

(71) Applicant: INDUSTRIAL TECHNOLOGY RESEARCH INSTITUTE, Hsinchu (TW)

(72) Inventors: Yen-Liang LI, Tainan City (TW); Ping-I PAN, Tainan City (TW); Chien-Chung HUANG, Tainan City (TW); Lung-Yu SUNG, Zhubei City (TW); Yi-Hua LIU, Zhubei City (TW); Shi-Quan HUANG, Taipei City (TW); Ching-Ju KUNG, New Taipei City (TW)

(73) Assignee: INDUSTRIAL TECHNOLOGY RESEARCH INSTITUTE, Hsinchu (TW)

(21) Appl. No.: 19/086,815

(22) Filed: Mar. 21, 2025

(30) Foreign Application Priority Data
Dec. 16, 2024 (TW) 113148941

(51) Int. Cl. H02J 7/00; G01R 31/392; H01M 10/44; H01M 10/48

(52) U.S. Cl. CPC H02J 7/84; H01M 10/44; H01M 10/486; H02J 7/82; H02J 7/933; G01R 31/392

(57) ABSTRACT

A charging evaluation method based on states of health of batteries comprises: providing one or more batteries in multiple types of states of health; charging one or more batteries by multiple types of charging methods; acquiring multiple types of battery parameters of the one or more batteries during the charging process; forming a radar chart corresponding to a single type of state of health based on the multiple types of battery parameters; calculating and comparing area proportions of the multiple types of charging methods on the radar chart; and determining the one with the highest area proportion among multiple types of charging methods to be the charging method applicable to an interval of state of health.

This application claims the benefits of the Taiwan application Serial No. 113148941 filed on Dec. 16, 2024, the disclosure of which is incorporated by reference herein in its entirety.

### TECHNICAL FIELD

The present invention relates to a charging evaluation method based on states of health of batteries and a use thereof.

### BACKGROUND

In the current battery field, chargers generally use a uniform charging method in their design, without considering the fact that batteries may gradually age as the charge and discharge cycles increase. Therefore, using a uniform charging method for aging batteries may cause the temperature to rise above expected levels during charging, increasing the risk of thermal runaway during charging. In light of this, there is an urgent need for a charging evaluation method based on states of health of the battery to reduce the temperature rise during charging and to enhance safety.

### SUMMARY

According to one aspect of the present invention, a charging evaluation method based on states of health of batteries is provided and comprises: providing one or more batteries in multiple types of states of health; charging one or more batteries by multiple types of charging methods; acquiring multiple types of battery parameters of the one or more batteries during the charging process; forming a radar chart corresponding to a single type of state of health based on the multiple types of battery parameters; calculating and comparing area proportions of the multiple types of charging methods on the radar chart; and determining the one with the highest area proportion among multiple types of charging methods to be a charging method applicable to an interval of state of health.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A illustrates a flowchart of a charging evaluation method based on states of health of batteries according to an embodiment of the present invention.

FIG. 1B is a detailed flowchart of the step S120 in FIG. 1A.

FIG. 2 illustrates one type of the multiple charging methods regarding the charging evaluation method based on states of health of batteries according to an embodiment of the present invention.

FIG. 3 illustrates one type of the multiple charging methods regarding the charging evaluation method based on states of health of batteries according to an embodiment of the present invention.

FIG. 4 illustrates one type of the multiple charging methods regarding the charging evaluation method based on states of health of batteries according to an embodiment of the present invention.

FIG. 5 illustrates one type of the multiple charging methods regarding the charging evaluation method based on states of health of batteries according to an embodiment of the present invention.

FIG. 6 illustrates one type of the multiple charging methods regarding the charging evaluation method based on states of health of batteries according to an embodiment of the present invention.

FIG. 7 illustrates an example of a radar chart formed by the charging evaluation method based on states of health of batteries according to an embodiment of the present invention.

FIG. 8 illustrates an example of a radar chart formed by the charging evaluation method based on states of health of batteries according to an embodiment of the present invention.

FIG. 9 illustrates an example of a radar chart formed by the charging evaluation method based on states of health of batteries according to an embodiment of the present invention.

### DETAILED DESCRIPTION

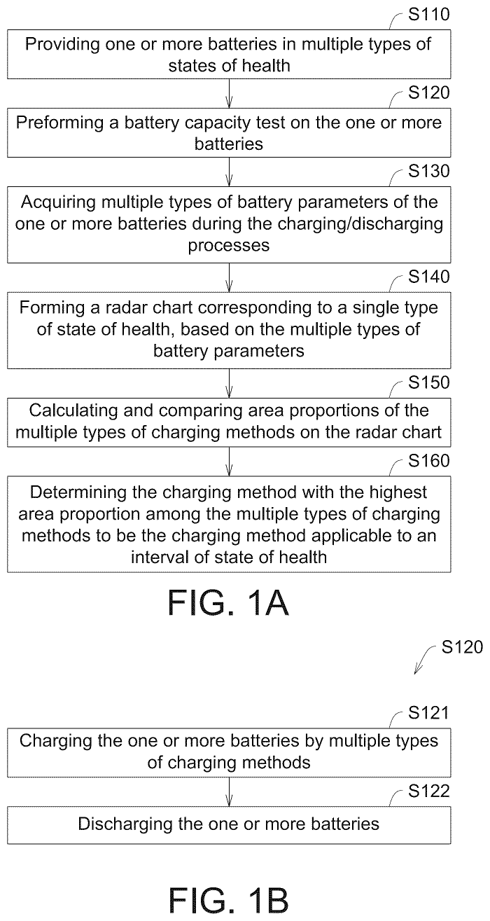

Please refer to FIG. 1A, which illustrates a flowchart of a charging evaluation method based on states of health of batteries according to an embodiment of the present invention. The charging evaluation method based on states of health of batteries in this embodiment mainly includes steps S110 to S160.

In the step S110, provide one or more batteries in multiple types of states of health (SOH). For example, ICR18650 lithium-ion batteries may be used. In one embodiment, at least two batteries are provided, each in a different state of health, such as providing three batteries with SOH of 100%, 95%, and 91%, respectively. In another embodiment, a single battery is provided, which is subjected to a battery aging treatment to be in the multiple types of states of health, such as providing a battery with SOH of 100%. When facing subsequent requirements for different SOH, the battery aging treatment is performed to make the single battery have SOH of 95% or 91%. The battery aging treatment may involve charging and discharging the battery to achieve a set number of charge-discharge cycles (e.g., 10 to 15 cycles, but not limited thereto) to accelerate the battery aging.

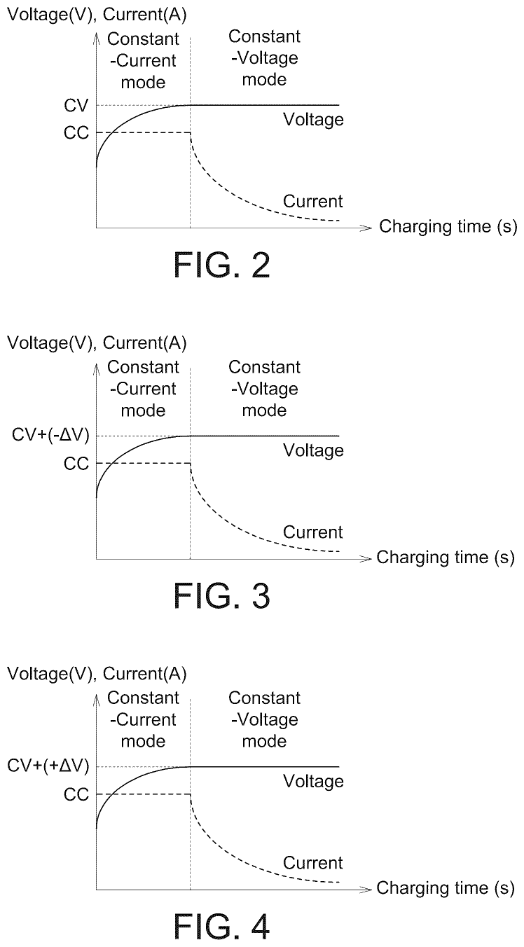

In the step S120, perform a battery capacity test on the one or more batteries. Please also refer to FIG. 1B and FIGS. 2-6, where FIG. 1B is a detailed flowchart of the step S120, and FIGS. 2-6 illustrate multiple types of charging methods regarding the charging evaluation method based on states of health of batteries according to an embodiment of the present invention. In this embodiment, as shown in FIG. 1B, the step S120 may be further divided into the step S121 and the step S122. In the step S121, charge the one or more batteries using multiple types of charging methods. After the step S121, the step S122 is performed to discharge the one or more batteries.

For example, in the step S121, five different charging methods may be used. FIGS. 2-4 illustrate schematic diagrams of Constant-Current Constant-Voltage (CC-CV) charging methods. In the Constant-Current Constant-Voltage charging method shown in FIG. 2, the battery is charged with a fixed charging current CC until the battery voltage reaches or exceeds a rated voltage CV of the battery, at which point the battery turns to be charged at the rated voltage CV (namely said constant voltage mode) until the current drops below a set current and charging is stopped. In the Constant-Current Constant-Voltage charging method shown in FIG. 3, the battery is charged with a fixed current CC until the battery voltage reaches or exceeds the sum of a rated voltage CV and a set negative value −ΔV (i.e., [CV+(−ΔV)]), at which point the battery turns to be charged at the voltage [CV+(−ΔV)] (namely said constant voltage mode) until the current drops below a set current and charging is stopped. In the Constant-Current Constant-Voltage charging method shown in FIG. 4, the battery is charged with a fixed current CC until the battery voltage reaches or exceeds the sum of the rated voltage CV and a set positive value+ΔV (i.e., [CV+(+ΔV)]), at which point the battery turns to be charged at the voltage [CV+(+ΔV)] (namely said constant voltage mode) until the current drops below a set current and charging is stopped. It can be known that the charging methods shown in FIGS. 2-4 are all Constant-Current Constant-Voltage charging methods, but these three charging methods have different cut-off voltages and therefore belong to different types.

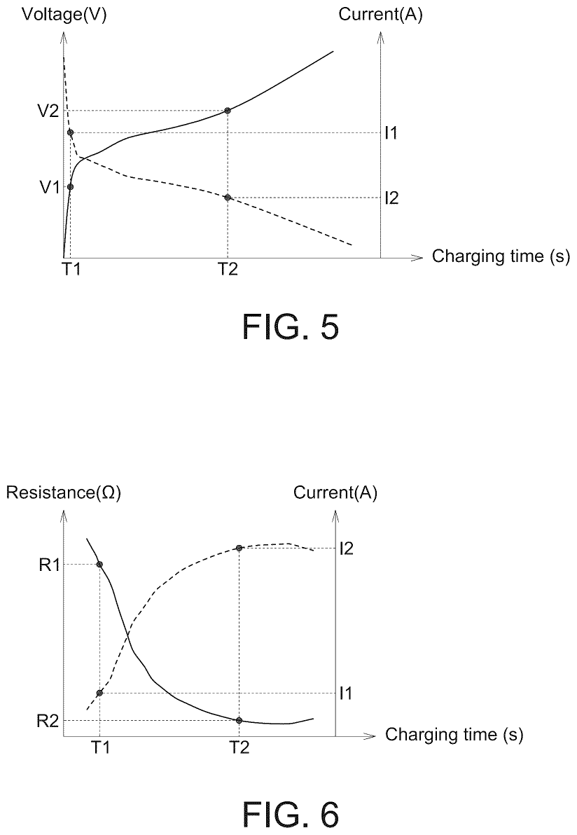

FIG. 5 illustrates the constant power charging stage of Constant-Power Constant-Voltage (CP-CV) charging method. In this charging method, as shown in FIG. 5, the battery is initially charged at a constant power (this stage is referred to as the constant power mode), where the charging power is the product of voltage and current. Specifically, the product of the voltage V1 and the current I1 at the time point T1 equals the product of the voltage V2 and the current I2 at the time point T2. The battery continues being charged in the constant power mode until the voltage of the battery reaches or exceeds a preset voltage, at which point the battery turns to be charged at the preset voltage (namely said constant voltage mode) until the current drops below a set current and charging is stopped. The charging power can be set based on the rated power of the battery. In one embodiment, the charging power is set to 0.5 times the rated power.

FIG. 6 illustrates the constant loss charging stage of Constant-Loss Constant-Voltage (CL-CV) charging method. In this charging method, as shown in FIG. 6, the battery is initially charged at a constant loss (this stage is referred to as the constant loss mode), where the charging loss is calculated as the product of the square of the current and the battery's equivalent resistance. Specifically, the product of the square of current I1 and the equivalent resistance R1 at the time point T1 equals the product of the square of current I2 and the equivalent resistance R2 at the time point T2. The battery continues being charged in the constant loss mode until the voltage of the battery reaches or exceeds a preset voltage, at which point the battery turns to be charged at the preset voltage (namely, said constant voltage mode) until the current drops below a set current and charging is stopped. Since the internal equivalent impedance of batteries varies at different states of charge (SOC), the charging current under the constant loss mode can be changed as different SOC for maintaining the same charging loss.

In an embodiment where three batteries are provided (with SOH of 100%, 95%, and 91%, respectively), each battery can be subjected to at least two of the five charging methods described in FIGS. 2-6. In another embodiment where a single battery is provided (with its SOH changes from 100% to 95%, and then to 91%), the single battery can be subjected to at least two of the five charging methods described in FIGS. 2-6 when its SOH is 100%. After the battery aging treatment to make SOH be 95%, the same at least two charging methods are applied to the single battery. Then, the battery aging treatment is performed again to make SOH be 91%, and the same at least two charging methods are applied to the single battery.

Next, in the step S122, discharge the one or more batteries. In this embodiment, one discharging method is used for all the batteries, but not limited thereto. Therefore, in this embodiment, the capacity measurement in the step S120 includes charging by multiple types of charging methods and discharging by the same type of discharging method. It should be note that in other embodiments, the step S120 may include only the step S121 and omit step S122, meaning that the battery capacity test in the step S120 may only involve the charging process, but not limited thereto.

In the step S130, acquire multiple types of battery parameters of the one or more batteries during the charging/discharging processes. For instance, the battery parameters of the battery with SOH of 100% during various charging methods, the battery parameters of the battery with SOH of 95% during various charging methods, and the battery parameters of the battery with SOH of 91% during various charging methods can be acquired. The multiple types of battery parameters regarding the charging process include a reciprocal of a maximum temperature rise, a reciprocal of an average temperature rise, a charging rate, and a charging capacity. The reciprocal of the maximum temperature rise (in unit such as ° C.) is the reciprocal of the difference between the battery surface temperature and the ambient temperature. The reciprocal of the average temperature rise (in units such as ° C.) is the reciprocal of the average value of the differences between the battery surface temperature sampled at multiple time points during the charging process and the ambient temperature. The charging rate is the reciprocal of the charging time (in units such as hours). Correspondingly, the battery parameters for the discharging process can also be acquired, such as the discharge capacity and the coulombic efficiency. The coulombic efficiency is the percentage ratio of the discharging capacity (in units such as Ah) of the battery to the charging capacity (in units such as Ah). Specifically, the information of these battery parameters can be acquired using an acquiring unit. The acquiring unit can be integrated into a controller or a processor. Furthermore, the acquiring unit can be implemented as a physical circuit formed using at least one semiconductor process, such as a semiconductor chip or a semiconductor package.

Based on an implementation test of the charging evaluation method based on states of health of the battery, the data of battery parameters corresponding to different states of health are provided as shown in Tables 1 to 3 below.

TABLE 1
battery parameters acquired by using five charging
methods for a battery with SOH of 100%.

| | Charging | Charging | Charging | Charging | Charging |
|---|---|---|---|---|---|
| | method | method | method | method | method |
| | of FIG. 2 | of FIG. 3 | of FIG. 4 | of FIG. 5 | of FIG. 6 |
| Reciprocal | 0.29 | 0.28 | 0.16 | 0.24 | 0.26 |
| of maximum | | | | | |
| temperature | | | | | |
| rise (1/° C.) | | | | | |
| Reciprocal | 0.37 | 0.41 | 0.21 | 0.33 | 0.35 |
| of average | | | | | |
| temperature | | | | | |
| rise (1/° C.) | | | | | |
| Charging | 2.57 | 2.37 | 2.60 | 2.60 | 2.61 |
| capacity | | | | | |
| (Ah) | | | | | |
| Discharging | 2.56 | 2.36 | 2.59 | 2.56 | 2.56 |
| capacity | | | | | |
| (Ah) | | | | | |
| Coulombic | 99.45 | 99.51 | 99.6 | 98.65 | 98.04 |
| efficiency | | | | | |
| (%) | | | | | |
| Charging | 0.44 | 0.48 | 0.44 | 0.43 | 0.42 |
| rate (1/h) | | | | | |

TABLE 2
battery parameters acquired by using five charging
methods for a battery with SOH of 95%.

| | Charging | Charging | Charging | Charging | Charging |
|---|---|---|---|---|---|
| | method | method | method | method | method |
| | of FIG. 2 | of FIG. 3 | of FIG. 4 | of FIG. 5 | of FIG. 6 |
| Reciprocal | 0.28 | 0.24 | 0.24 | 0.20 | 0.32 |
| of maximum | | | | | |
| temperature | | | | | |
| rise (1/° C.) | | | | | |
| Reciprocal | 0.43 | 0.34 | 0.33 | 0.31 | 0.46 |
| of average | | | | | |
| temperature | | | | | |
| rise (1/° C.) | | | | | |
| Charging | 2.51 | 2.29 | 2.50 | 2.47 | 2.49 |
| capacity | | | | | |
| (Ah) | | | | | |
| Discharging | 2.48 | 2.24 | 2.47 | 2.40 | 2.47 |
| capacity | | | | | |
| (Ah) | | | | | |
| Coulombic | 98.67 | 97.74 | 98.78 | 97.12 | 99.48 |
| efficiency | | | | | |
| (%) | | | | | |
| Charging | 0.43 | 0.46 | 0.43 | 0.40 | 0.41 |
| rate (1/h) | | | | | |

TABLE 3
battery parameters acquired by using five charging
methods for a battery with SOH of 91%.

| | Charging | Charging | Charging | Charging | Charging |
|---|---|---|---|---|---|
| | method | method | method | method | method |
| | of FIG. 2 | of FIG. 3 | of FIG. 4 | of FIG. 5 | of FIG. 6 |
| Reciprocal | 0.14 | 0.16 | 0.16 | 0.19 | 0.22 |
| of maximum | | | | | |
| temperature | | | | | |
| rise (1/° C.) | | | | | |
| Reciprocal | 0.20 | 0.24 | 0.25 | 0.34 | 0.32 |
| of average | | | | | |
| temperature | | | | | |
| rise (1/° C.) | | | | | |
| Charging | 2.40 | 2.15 | 2.33 | 2.4 | 2.41 |
| capacity | | | | | |
| (Ah) | | | | | |
| Discharging | 2.32 | 2.12 | 2.25 | 2.34 | 2.34 |
| capacity | | | | | |
| (Ah) | | | | | |
| Coulombic | 96.67 | 98.6 | 96.66 | 97.1 | 97.1 |
| efficiency | | | | | |
| (%) | | | | | |
| Charging | 0.39 | 0.40 | 0.38 | 0.39 | 0.37 |
| rate (1/h) | | | | | |

In the step S140, form a radar chart corresponding to a single state of health, based on the multiple types of battery parameters. As described previously, after charging the one or more batteries by multiple types of charging methods, the one or more batteries may be discharged, allowing for the acquisition of battery parameters from both the charging and discharging processes. Since forming a radar chart requires at least three indicators (e.g., three indicators for forming a triangular radar chart, four indicators for forming a quadrilateral radar chart, five indicators for forming a pentagonal radar chart, and six indicators for forming a hexagonal radar chart), the battery parameters from the charging and discharging processes may include at least three parameters selected from the following: the reciprocal of the maximum temperature rise, the reciprocal of the average temperature rise, the charging rate, the charging capacity, the discharging capacity, and the coulomb efficiency. However, if the batteries are not discharged, only the battery parameters from the charging process are acquired. The battery parameters from the charging process include at least three battery parameters selected from the following: the reciprocal of the maximum temperature rise, the reciprocal of the average temperature rise, the charging rate, and the charging capacity.

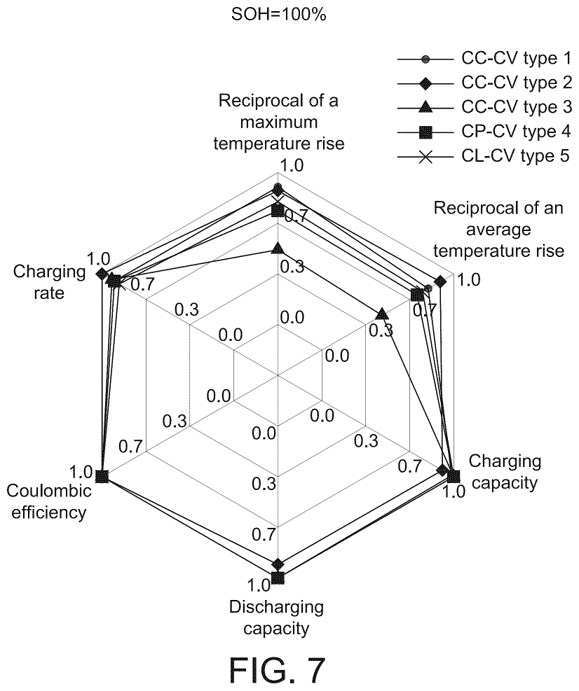

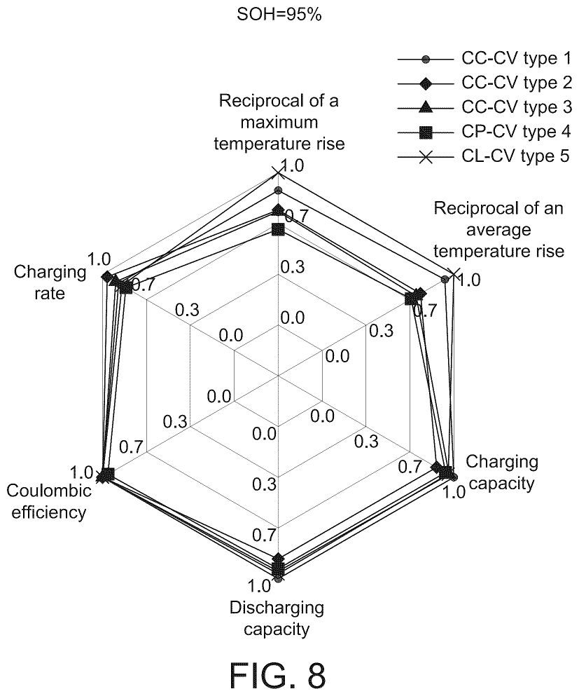

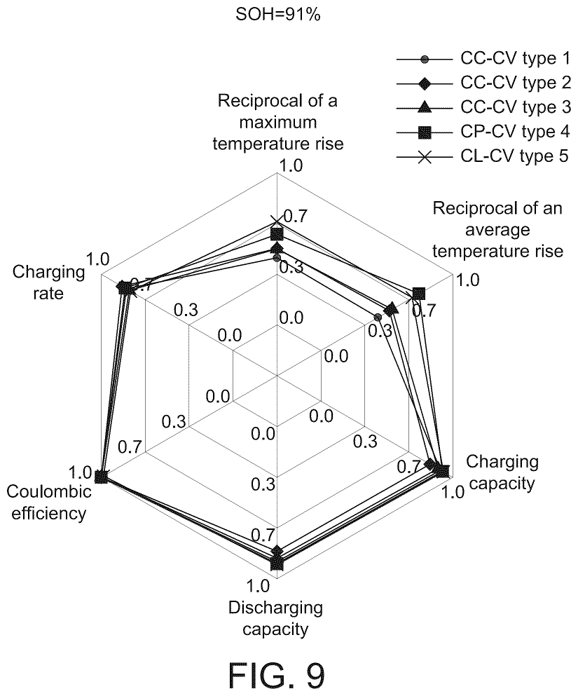

Please further refer to FIGS. 7 to 9 for examples of radar charts formed based on the charging evaluation method. FIG. 7 corresponds to the data in Table 1, FIG. 8 corresponds to the data in Table 2, and FIG. 9 corresponds to the data in Table 3.

In one embodiment, for instance, all six listed battery parameters (namely, the reciprocal of the maximum temperature rise, the reciprocal of the average temperature rise, the charging rate, the charging capacity, the discharging capacity, and the coulombic efficiency) are acquired in the step S130, and then in the step S140 these six battery parameters are used to form hexagonal radar charts, as shown in FIGS. 7 to 9. Specifically, the radar charts shown in FIGS. 7 to 9 are formed by performing a normalization process on the battery parameters to create hexagonal radar charts corresponding to a single state of health. The normalization process can involve calculating the ratio of a specific battery parameter acquired from a particular charging method for a single state of health, as listed in Tables 1 to 3, to the maximum value of the same parameter across all states of health and all charging methods. For example, in Table 1, the reciprocal of the maximum temperature rise for a battery with SOH of 100% using the charging method shown in FIG. 2 is 0.29. The maximum value of the reciprocal of the maximum temperature rise across all SOHs and charging methods is 0.32 (as shown in Table 2, from a battery with SOH of 95% using the charging method of FIG. 6). Hence, the normalized value is 0.29/0.32=0.90625. As illustrated in FIG. 7, a node on the radar chart is plotted at the corresponding position between 0.7 and 1.0 based on this value of 0.90625. All battery parameter data in Tables 1 to 3 can undergo similar normalization, resulting in the formation of radar charts.

In the step S150, calculate and compare area proportions corresponding to the various charging methods on the radar chart. The area proportion represents the proportion of the contour area corresponding to each of the five charging methods on the radar chart relative to the total contour area of the radar chart. Specifically, a computing unit can be used to calculate and compare the aforementioned area proportion information. The computing unit can be integrated into a controller or a processor. Furthermore, the computing unit can be implemented as physical circuitry formed using at least one semiconductor manufacturing process, such as a semiconductor chip or a semiconductor package. Based on the implementation test of the charging evaluation method according to states of health, the data for the area proportions corresponding to radar charts for different states of health are provided in Table 4 below:

TABLE 4
proportion of the contours of the five charging methods on
each radar chart to the total contour of the radar chart.

| | Charging | Charging | Charging | Charging | Charging |
|---|---|---|---|---|---|
| | method | method | method | method | method |
| | of FIG. 2 | of FIG. 3 | of FIG. 4 | of FIG. 5 | of FIG. 6 |
| SOH of | 90.25% | 89.92% | 74.69% | 84.39% | 86.19% |
| 100% in | | | | | |
| FIG. 7 | | | | | |
| SOH of | 90.64% | 80.47% | 82.71% | 59.49% | 94.04% |
| 95% in | | | | | |
| FIG. 8 | | | | | |
| SOH of | 66.32% | 66.36% | 67.98% | 75.71% | 75.82% |
| 91% in | | | | | |
| FIG. 9 | | | | | |

Based on the data in Table 4, the charging method corresponding to the highest area proportion for SOH of 100% is the charging method shown in FIG. 2. For SOH of 95%, the charging method with the highest area proportion is the charging method shown in FIG. 6. For SOH of 91%, the charging method with the highest area proportion is the charging method shown in FIG. 6.

In the step S160, determine the charging method with the highest area proportion among the multiple types of charging methods to be the charging method applicable to an interval of state of health. Specifically, a determination unit may be used to determine the charging method with the highest area proportion as the optimal charging method applicable to an interval of state of health. The determination unit may be integrated into a controller or processor. Additionally, the determination unit may be implemented as a physical circuit formed using at least one semiconductor process, such as a semiconductor chip or package. Based on the data comparison in Table 4, the charging method shown in FIG. 2 is determined to be the charging method applicable to the interval of state of health between 95% and 100%. The charging method shown in FIG. 2 is determined to be the charging method applicable to the interval of state of health between 91% and 95%. The charging method shown in FIG. 6 is determined to be the charging method applicable to the interval of state of health below 91%.

As described above, the interval of state of health may include an interval defined by one (e.g., SOH of 100%) of the multiple types of states of health and another one (e.g., SOH of 95%) of the multiple types of state of health that is lower and closest to the one, and may also include an interval defined by a lowest one (e.g., SOH of 91%) of the multiple types of states of health and a state of health of zero. In other words, the charging evaluation method based on states of health of batteries of the present invention aims to select the charging method with the highest area proportion on the radar chart as the optimal charging method. This charging method is able to effectively improve the temperature rise condition during the battery charging and to enhance safety.

Furthermore, the present invention also comprises the use of the charging evaluation method based on states of health of batteries, wherein the charging method applicable to the interval of state of health is used to charge a battery in a specific state of health, wherein the specific state of health is within the interval of state of health. For example, if the specific state of health is 80%, which lies within the interval of state of health below 91%, the charging method shown in FIG. 6 can be used to charge this battery. This improves the temperature rise condition during charging and enhances safety.

In summary, the present disclosure provides a charging evaluation method based on states of health of batteries and a use thereof. The charging evaluation method is related to performing a battery capacity test (e.g., multiple types of charging and discharging methods) on batteries in multiple types of states of health, acquiring multiple types of battery parameters during the charging/discharging processes, forming radar charts corresponding to a single state of health using these parameters, calculating and comparing the area proportions of different charging methods on the radar charts, and finally determining the charging method with the highest area proportion to be the charging method applicable to an interval of state of health.

It will be apparent to those skilled in the art that various modifications and variations may be made to the disclosed embodiments. It is intended that the specification and examples be considered as exemplars only, with a true scope of the disclosure being indicated by the following claims and their equivalents.

What is claimed is:

1. A charging evaluation method based on states of health of one or more batteries, comprising:
providing one or more batteries in multiple types of states of health;
charging one or more batteries by multiple types of charging methods;
acquiring multiple types of battery parameters of the one or more batteries during the charging process;
forming a radar chart corresponding to a single type of state of health, based on the multiple types of battery parameters;
calculating and comparing area proportions of the multiple types of charging methods on the radar chart; and
determining the charging method with the highest area proportion among the multiple types of charging methods to be the charging method applicable to an interval of state of health.

2. The charging evaluation method based on states of health of batteries according to claim 1, wherein the one or more batteries is a single battery, the single battery is subjected to a battery aging treatment to be in the multiple types of states of health.

3. The charging evaluation method based on states of health of batteries according to claim 1, wherein the one or more batteries are two batteries, the two batteries are respectively in different states of health.

4. The charging evaluation method based on states of health of batteries according to claim 1, wherein the multiple types of charging methods include at least two charging methods selected from the following: three Constant-Current Constant-Voltage charging methods with different cut-off voltages, a Constant-Power Constant-Voltage charging method, and a Constant-Loss Constant-Voltage charging method.

5. The charging evaluation method based on states of health of batteries according to claim 1, wherein the multiple types of battery parameters include at least three parameters selected from the following: a reciprocal of a maximum temperature rise, a reciprocal of an average temperature rise, a charging rate, and a charging capacity.

6. The charging evaluation method based on states of health of batteries according to claim 1, wherein after charging the one or more batteries in multiple types of charging methods, the one or more batteries are discharged.

7. The charging evaluation method based on states of health of batteries according to claim 6, wherein multiple types of battery parameters of the one or more batteries during the discharging process are acquired.

8. The charging evaluation method based on states of health of batteries according to claim 7, wherein the multiple types of battery parameters include at least three parameters selected from the following: a reciprocal of a maximum temperature rise, a reciprocal of an average temperature rise, a charging rate, a charging capacity, a discharging capacity, and a coulombic efficiency.

9. The charging evaluation method based on states of health of batteries according to claim 1, wherein the radar chart corresponding to the single type of state of health is formed by performing a normalization process on the multiple types of battery parameters.

10. The charging evaluation method based on states of health of batteries according to claim 1, wherein the interval of state of health includes an interval defined by one of the multiple types of states of health and another one of the multiple types of states of health that is lower and closest to the one.

11. The charging evaluation method based on states of health of batteries according to claim 1, wherein the interval of state of health includes an interval defined by a lowest one of the multiple types of states of health and a state of health of zero.

12. A use of the charging evaluation method based on states of health of batteries according to claim 1, wherein the charging method applicable to the interval of state of health is used to charge a battery in a specific state of health, and the specific state of health is within the interval of state of health.

13. A use of the charging evaluation method based on states of health of batteries according to claim 4, wherein the charging method applicable to the interval of state of health is used to charge a battery in a specific state of health, and the specific state of health is within the interval of state of health.

14. A use of the charging evaluation method based on states of health of batteries according to claim 5, wherein the charging method applicable to the interval of state of health is used to charge a battery in a specific state of health, and the specific state of health is within the interval of state of health.

15. A use of the charging evaluation method based on states of health of batteries according to claim 6, wherein the charging method applicable to the interval of state of health is used to charge a battery in a specific state of health, and the specific state of health is within the interval of state of health.

16. A use of the charging evaluation method based on states of health of batteries according to claim 7, wherein the charging method applicable to the interval of state of health is used to charge a battery in a specific state of health, and the specific state of health is within the interval of state of health.

17. A use of the charging evaluation method based on states of health of batteries according to claim 8, wherein the charging method applicable to the interval of state of health is used to charge a battery in a specific state of health, and the specific state of health is within the interval of state of health.

18. A use of the charging evaluation method based on states of health of batteries according to claim 9, wherein the charging method applicable to the interval of state of health is used to charge a battery in a specific state of health, and the specific state of health is within the interval of state of health.

19. A use of the charging evaluation method based on states of health of batteries according to claim 10, wherein the charging method applicable to the interval of state of health is used to charge a battery in a specific state of health, and the specific state of health is within the interval of state of health.

20. A use of the charging evaluation method based on states of health of batteries according to claim 11, wherein the charging method applicable to the interval of state of health is used to charge a battery in a specific state of health, and the specific state of health is within the interval of state of health.
